(19) United States
(12) Patent Application Publication
(10) Pub. No.: US 2025/0169301 A1
(43) Pub. Date: May 22, 2025

(54) DISPLAY PANEL AND DISPLAY DEVICE

(71) Applicants: Hefei BOE Joint Technology Co.,Ltd., Hefei, Anhui (CN); BOE Technology Group Co., Ltd., Beijing (CN)

(72) Inventors: Liu WU, Beijing (CN); Yongqian LI, Beijing (CN)

(21) Appl. No.: 18/841,689

(22) PCT Filed: Oct. 9, 2023
(86) PCT No.: PCT/CN2023/123536

§ 371 Date: Aug. 27, 2024

(30) Foreign Application Priority Data
Nov. 10, 2022 (CN) 202211407849.1

(51) Int. Cl. H10K 59/131; H10D 86/40; H10D 86/60; H10K 59/121; H10K 59/80

(52) U.S. Cl. CPC H10K 59/131; H10K 59/1213; H10K 59/873; H10D 86/441; H10D 86/60

(57) ABSTRACT

A display panel, comprising: a base substrate, a display structure layer, a packaging structure layer, and a plurality of signal lead-out lines. The base substrate comprises: a display area, a signal access area located on one side of the display area, and a peripheral wiring area located between the display area and the signal access area. The packaging structure layer extends from the display area to the peripheral wiring area. The peripheral wiring area comprises a first area located on the side of a packaging boundary of the packaging structure layer close to the signal access area. The plurality of signal lead-out lines are located in the peripheral wiring area. At least one signal lead-out line comprises a first wire located in the first area, wherein the first wire is a double-layer wire.

### CROSS-REFERENCE TO RELATED APPLICATIONS

The present application is a U.S. National Phase Entry of International Application No. PCT/CN2023/123536 having an international filing date of Oct. 9, 2023, which claims priority to Chinese Patent Application No. 202211407849.1, filed to the CNIPA on Nov. 10, 2022, which are hereby incorporated into the present application by reference in their entireties.

### TECHNICAL FIELD

The present disclosure relates to, but is not limited to, the field of display technology, in particular to a display panel and a display device.

### BACKGROUND

With constant development of display technologies, there are more and more kinds of display products, e.g., a Liquid Crystal Display (LCD), an Organic Light emitting Diode (OLED) display, a Plasma Display Panel (PDP), and a Field Emission Display (FED).

### SUMMARY

The following is a summary of subject matters described herein in detail. This summary is not intended to limit the protection scope of claims.

Embodiments of the present disclosure provide a display panel and a display device.

In one aspect, the present embodiment provides a display panel including: a base substrate, a display structure layer, an encapsulation structure layer, and a plurality of signal lead-out lines. The base substrate includes: a display region, a signal access region located on a side of the display region, and a peripheral wiring region located between the display region and the signal access region. The display structure layer is located in the display region. The encapsulation structure layer is located on a side of the display structure layer away from the base substrate. The encapsulation structure layer extends from the display region to the peripheral wiring region. The peripheral wiring region includes: a first region located on a side of an encapsulation boundary of the encapsulation structure layer close to the signal access region. A plurality of signal lead-out lines are located in the peripheral wiring region. At least one signal lead-out line includes a first wire located in the first region, wherein the first wire is a double-layer wire.

In some exemplary implementations, the peripheral wiring region further includes: a second region located on a side of the encapsulation boundary of the encapsulation structure layer close to the display region; wherein a length of the first wire extending to the second region is less than or equal to 300 microns.

In some exemplary implementations, the first wire includes: a first sub-wire and a second sub-wire electrically connected to each other, wherein the first sub-wire is located on a side of the second sub-wire away from the base substrate; and orthographic projections of the first sub-wire and the second sub-wire on the base substrate at least partially overlap.

In some exemplary implementations, a resistivity of a material of the first sub-wire is less than a resistivity of a material of the second sub-wire.

In some exemplary implementations, the material of the first sub-wire and the material of the second sub-wire are both a metallic material.

In some exemplary implementations, the first sub-wire is a titanium-aluminum-titanium stacked structure, and the material of the second sub-wire includes molybdenum.

In some exemplary implementations, at least one insulation layer is provided between the first sub-wire and the second sub-wire, and the at least one insulation layer is provided with a plurality of vias arranged in an array, and the first sub-wire is electrically connected to the second sub-wire through the plurality of vias.

In some exemplary implementations, the peripheral wiring region further includes: a second region located on a side of the encapsulation boundary of the encapsulation structure layer close to the display region; and the at least one first signal lead-out line further includes: a second wire located in the second region, the second wire and the first sub-wire of the first wire form an integrated structure.

In some exemplary implementations, the signal access region includes a plurality of signal access pins, and the second sub-wire is electrically connected to at least one signal access pin.

In some exemplary implementations, in a direction perpendicular to the display panel, the display panel includes: a semiconductor layer, a first gate metal layer, a second gate metal layer, a first source-drain metal layer and a second source-drain metal layer, which are sequentially arranged on the base substrate. Herein the first sub-wire is located on the first source-drain metal layer, and the second sub-wire is located on the first gate metal layer or the second gate metal layer.

In some exemplary implementations, a first planarization layer and a first passivation layer are sequentially disposed between the first source-drain metal layer and the second source-drain metal layer, and a second passivation layer and a second planarization layer are sequentially disposed on a side of the second source-drain metal layer away from the base substrate.

In some exemplary implementations, the peripheral wiring region has a first isolation region, at least one of a first planarization layer and a second planarization layer within the first isolation region is removed, and the first isolation region partially overlaps with the encapsulation structure layer; and the first wire partially overlaps with the first isolation region.

In some exemplary implementations, the plurality of signal lead-out lines include: a plurality of data fan-out lines; or include: a plurality of data fan-out lines and a plurality of drive control lines.

In some exemplary implementations, the base substrate is a rigid substrate.

In another aspect, a display device is provided in an embodiment of the present disclosure, which includes the aforementioned display panel.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of an appearance of a display device.

FIG. 2 is a schematic diagram of a structure of a display device.

FIG. 3 is an equivalent circuit diagram of a pixel circuit.

FIG. 4 is a schematic partial cross-sectional diagram of a structure of a display region of a display panel according to at least one embodiment of the present disclosure.

FIG. 5 is a schematic diagram of a first peripheral region of a display panel according to at least one embodiment of the present disclosure.

FIG. 6 is a schematic partial diagram of a first peripheral region according to at least one embodiment of the present disclosure.

FIGS. 7 and 8 are schematic partial diagrams of film layers of a first peripheral region according to at least one embodiment of the present disclosure.

FIG. 9 is a schematic partial diagram of a peripheral wiring region according to at least one embodiment of the present disclosure.

FIG. 10 is a schematic diagram of a first source-drain metal layer in FIG. 9.

FIG. 11 is a schematic diagram of a first gate metal layer in FIG. 9.

FIG. 12 is a schematic partial diagram of a first region according to at least one embodiment of the present disclosure.

FIG. 13 illustrates schematically a partial cross-sectional view taken along a direction Q-Q′ in FIG. 12.

FIG. 14 is a schematic diagram of a first gate metal layer in FIG. 12.

FIG. 15 is a schematic partial diagram of a first region after a second insulation layer is formed in FIG. 12.

### DETAILED DESCRIPTION

The embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, to distinguish two electrodes of a transistor except a gate, one of the electrodes is referred to as a first electrode and the other electrode is referred to as a second electrode. The first electrode may be a source or a drain, and the second electrode may be a drain or a source. In a case where transistors with opposite polarities are used, or in a case where a direction of a current is changed during operation of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. In following description, “A extends along a B direction” means “a main body portion of A extends along a B direction”.

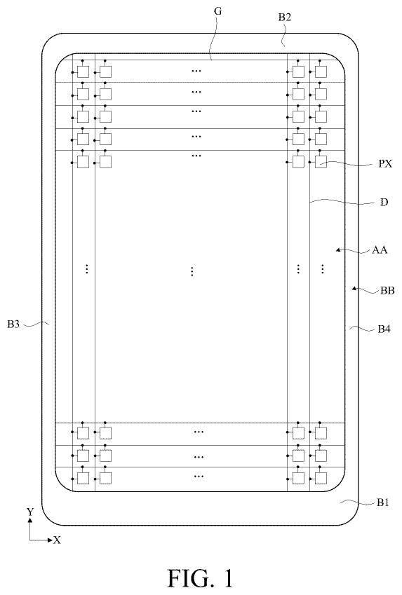

FIG. 1 is a schematic diagram of an appearance of a display device, which has a rectangular shape with rounded chamfers. The display device may include a display panel. In some examples, the display panel may be a closed polygon including linear sides, a circle or an ellipse including a curved side, a semi-circle or semi-ellipse including a linear side and a curved side, or the like. In some examples, at least some corners of the display panel may be curves when the display panel has linear sides. A part at an intersection of adjacent linear sides may be replaced with a curve with a predetermined curvature when the display panel has a rectangular shape. Herein, the curvature may be set according to different positions of the curve. For example, the curvature may be changed according to a starting position of the curve, a length of the curve, etc.

In some examples, as shown in FIG. 1, the display panel may include a display region AA and a peripheral region BB at a periphery of the display region AA. In some examples, the display region AA may include a first edge (lower edge) and a second edge (upper edge) oppositely disposed in the second direction Y, and a third edge (left edge) and a fourth edge (right edge) oppositely disposed in the first direction X. Adjacent edges may be connected by arc chamfering to form a quadrilateral shape with rounded corners. In some examples, the peripheral region BB may include a first peripheral region (lower bezel) B1 and a second peripheral region (upper bezel) B2 oppositely disposed in the second direction Y, and a third peripheral region (left bezel) B3 and a fourth peripheral region (right bezel) B4 oppositely disposed in the first direction X. The first peripheral region B1 is in communication with the third peripheral region B3 and the fourth peripheral region B4, and the second peripheral region B2 is in communication with the third peripheral region B3 and the fourth peripheral region B4.

In some examples, as shown in FIG. 1, the display region AA at least includes a plurality of sub-pixels PX, a plurality of gate lines G, and a plurality of data lines D. A plurality of gate lines G may extend in a first direction X, and a plurality of data lines D may extend in a second direction Y. Orthographic projections of the plurality of gate lines G and the plurality of data lines D on the display panel may be intersected to form a plurality of sub-pixel regions, and a sub-pixel PX is provided in each sub-pixel region. The plurality of data lines D are electrically connected with a plurality of sub-pixels PX, and may be configured to provide data signals to the plurality of sub-pixels PX. The plurality of gate lines G are electrically connected with the plurality of sub-pixels PX, and may be configured to provide gate control signals to the plurality of sub-pixels PX. In some examples, the gate control signals may include a scan signal or may include a scan signal and a light emitting control signal.

In some examples, as shown in FIG. 1, the first direction X may be an extension direction (row direction) of the gate lines G in the display region AA, and the second direction Y may be an extension direction (column direction) of the data lines D in the display region AA. The first direction X and the second direction Y may be perpendicular to each other.

In some examples, one pixel unit of the display region AA may include three sub-pixels, and the three sub-pixels may be a red sub-pixel, a green sub-pixel, and a blue sub-pixel, respectively. However, the present embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a manner like a Chinese character “ [symbol] ”; when one pixel unit includes four sub-pixels, the four sub-pixels may be arranged in parallel in a horizontal direction, in parallel in a vertical direction, or in a shape of a square. However, the present embodiment is not limited thereto.

In some examples, a sub-pixel may include a pixel circuit and a light emitting element electrically connected with the pixel circuit. The pixel circuit may include a plurality of transistors and at least one capacitor. For example, the pixel circuit may be a 3T1C structure, a 7T1C structure, a 5T1C structure, an 8T1C structure, or an 8T2C structure, etc., wherein T in the above circuit structures refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P-type transistors or may be N-type transistors. Use of a same type of transistors in the pixel circuit may simplify a process flow, reduce a process difficulty of the display substrate, and improve a yield of products. In some other examples, the plurality of transistors in the pixel circuit may include a P-type transistor and an N-type transistor.

In some examples, a plurality of transistors in the pixel circuit may employ low-temperature polysilicon thin-film transistors. The active layer of the low temperature polysilicon thin-film transistor uses Low Temperature Poly-silicon (LTPS). The low temperature poly-silicon thin film transistor has advantages such as high migration rate and fast charging.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the present embodiment is not limited thereto.

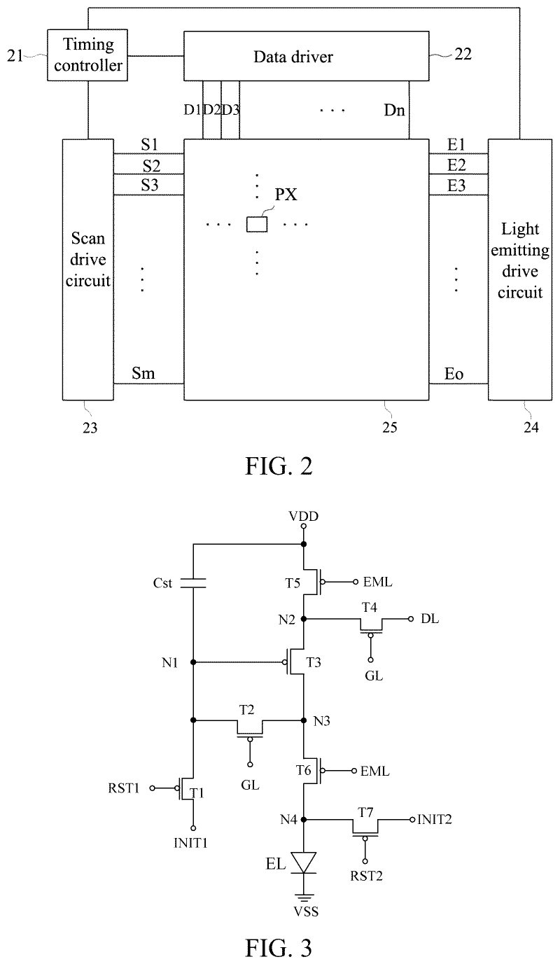

FIG. 2 is a schematic diagram of a structure of a display device. In some examples, as shown in FIG. 2, the display device may include a timing controller 21, a data driver 22, a scan drive circuit 23, a light emitting drive circuit 24 and a display panel 25. In some examples, the display region of the display panel 25 may include a plurality of sub-pixels PX arranged regularly. The scan drive circuit 23 may be configured to provide a scan signal to a sub-pixel PX along a scan line. The data driver 22 may be configured to provide a data voltage to a sub-pixel PX along a data line. The light emitting drive circuit 24 may be configured to provide a light emitting control signal to a sub-pixel PX along a light emitting control line. The timing controller 21 may be configured to control the scan drive circuit 23, the light emitting drive circuit 24 and the data driver 22.

In some examples, as shown in FIG. 2, the timing controller 21 may provide to the data driver 22 with a gray-scale value and a control signal suitable for a specification of the data driver 22; and the timing controller 21 may provide to the scan drive circuit 23 with a scan clock signal, a scan start signal, etc., suitable for a specification of the scan drive circuit 23; and the timing controller 21 may provide to the light emitting drive circuit 24 with a light emitting clock signal, a light emitting start signal, etc., suitable for a specification of the light emitting drive circuit 24. The data driver 22 may generate data voltages, which will be provided to data lines D1 to Dn, using the gray-scale value and the control signal received from the timing controller 21. For example, the data driver 22 may sample the gray-scale value using the clock signal and apply the data voltages corresponding to the gray-scale value to the data lines D1 to Dn using a sub-pixel row as a unit. The scan drive circuit 23 may receive the scan clock signal, the scan start signal, etc., from the timing controller 21 to generate scan signals to be provided to scan lines S1 to Sm. For example, the scan drive circuit 23 may sequentially provide scan signals with on-level pulses to scan lines. In some examples, the scan drive circuit 23 may include a shift register and may generate a scan signal by means of sequentially transmitting a scan start signal provided in a form of an on-level pulse to a next-stage circuit under control of a scan clock signal. The light emitting drive circuit 24 may receive the light emitting clock signal, the light emitting start signal, etc., from the timing controller 21 to generate light emitting control signals to be provided to light emitting control lines E1 to Eo. For example, the light-emitting drive circuit 24 may provide sequentially light-emitting start signals with off-level pulses to the light-emitting control lines. The light-emitting drive circuit 24 may include a shift register, and generate a light-emitting control signal by means of sequentially transmitting a light-emitting start signal provided in a form of an off-level pulse to a next-stage circuit under control of a light-emitting clock signal. Herein, n, m, and o are all natural numbers.

In some examples, the scan drive circuit and the light emitting drive circuit may be directly disposed on the display panel. For example, the scan drive circuit may be disposed at the third peripheral region of the display panel, and the light emitting drive circuit may be disposed at the fourth peripheral region of the display panel. Or, the third peripheral region and the fourth peripheral region of the display panel may be both provided with the scan drive circuit and the light emitting drive circuit. In some examples, the scan drive circuit and the light emitting drive circuit may be formed together with the sub-pixels in the process of forming the pixel circuit of the sub-pixels.

In some examples, the data driver may be disposed on a separate chip or printed circuit board to be connected to the sub-pixels through the signal access pins on the display panel. For example, the data driver may be formed and disposed at the first peripheral region of the display panel using a chip on glass, a chip on plastics, a chip on film, etc., to be connected to the signal access pins. The timing controller may be arranged separately from or integrally with the data driver. However, the present embodiment is not limited thereto. In some examples, the data driver may be directly disposed on the display panel.

FIG. 3 is an equivalent circuit diagram of a pixel circuit. In some examples, as shown in FIG. 3, the pixel circuit of this example may include seven transistors (i.e. a first transistor T1 to a seventh transistor T7) and one storage capacitor Cst. A gate of the third transistor T3 is electrically connected with a first node N1, a first electrode of the third transistor T3 is electrically connected with a second node N2, and a second electrode of the third transistor T3 is connected with the third node N3. The third transistor T3 may be referred to as a drive transistor. A gate of the fourth transistor T4 is electrically connected with the first scan line GL, a first electrode of the fourth transistor T4 is electrically connected with the data line DL, and a second electrode of the fourth transistor T4 is electrically connected with the first electrode of the third transistor T3. The fourth transistor T4 may be referred to as a data writing transistor. A gate of the second transistor T2 is electrically connected with the first scan line GL, a first electrode of the second transistor T2 is electrically connected with the gate of the third transistor T3, and a second electrode of the second transistor T2 is electrically connected with the second electrode of the third transistor T3. The second transistor T2 may also be referred to as a threshold compensation transistor. A gate of the fifth transistor T5 is electrically connected with the light emitting control line EML, a first electrode of the fifth transistor T5 is electrically connected with the second power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and configured to reset the gate of the third transistor T3, and the seventh transistor T7 is electrically connected with the anode of the light emitting element EL and configured to reset the anode of the light emitting element EL. A gate of the first transistor T1 is electrically connected with a second scan line RST1, a first electrode of the first transistor T1 is electrically connected with a first initial signal line INIT1, and a second electrode of the first transistor T1 is electrically connected with the gate of the third transistor T3. A gate of the seventh transistor T7 is connected with the third scan line RST2, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first capacitor plate of the storage capacitor Cst is electrically connected with the gate of the third transistor T3, and a second capacitor plate of the storage capacitor Cst is electrically connected with the second power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, the fourth node N4 is a connection point for the sixth transistor T6, the seventh transistor T7, and the light emitting element EL.

In some examples, the first transistor T1 to the seventh transistor T7 may be P-type transistors or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In some examples, the second power supply line VDD may be configured to provide a constant second voltage signal for a pixel circuit, the first power supply line VSS may be configured to provide a constant first voltage signal to a pixel circuit, wherein the second voltage signal may be greater than the first voltage signal. The first scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the second scan line RST1 may be configured to provide a first reset control signal RESET1 to the pixel circuit, and the third scan line RST2 may be configured to provide a second reset control signal RESET2 to the pixel circuit. In some examples, a second scan line RST1 electrically connected with a pixel circuit in an n-th row may be electrically connected with a first scan line GL of a pixel circuit in an (n−1)-th row, so as to be inputted with a scan signal SCAN(n−1). That is, a first reset control signal RESET1(n) is the same as the scan signal SCAN(n−1). A third scan line RST2 of the pixel circuit in the n-th row may be electrically connected with a first scan line GL of the pixel circuit in the n-th row, so as to be inputted with a scan signal SCAN(n). That is, a second reset control signal RESET2(n) may be the same as the scan signal SCAN(n). Herein, n is an integer greater than 0. Thus, signal lines of the display substrate may be reduced, and a narrow bezel design of the display substrate may be achieved. However, the present embodiment is not limited thereto.

In some examples, the first initial signal line INIT1 is configured to provide a first initial signal to the pixel circuit, and the second initial signal line INIT2 is configured to provide a second initial signal to the pixel circuit. For example, the first initial signal may be different from the second initial signal. The first initial signal and the second initial signal may be constant voltage signals, and their magnitudes may be between a first voltage signal and a second voltage signal, but are not limited thereto. In other examples, the first initial signal and the second initial signal may be the same and only the first initial signal line may be provided to provide the first initial signal.

In some implementations, during the preparation process of the LTPS display panel, a signal wire in the first peripheral region may experience poor signal transmission. After research, the inventor of the present application found that in the preparation process of the LTPS display panel, the signal wire in the first peripheral region is made of a metal material with relatively high resistivity (such as molybdenum (Mo), and the impedance of molybdenum per unit area is about 0.5 ohms (Ω)), there is a situation where the signal transmission effect is significantly affected by the wire impedance. After the signal wire is prepared with a material with smaller resistivity (for example, the titanium/aluminum/titanium stacked structure, the impedance of the titanium/aluminum/titanium stacked structure per unit area is about 0.05 Ω), although the wire impedance can be reduced, limited by the preparation process, there is a situation where aluminum oxidation causes titanium on the top layer to collapse and thus the signal transmission is affected. For example, in the preparation process of the display panel, the planarization layer is prepared after the preparation of the titanium/aluminum/titanium stacked structure. Once there is a problem in the glue coating process of the planarization layer, the aluminum is prone to oxidation, resulting in the collapse of the titanium on the upper layer of the aluminum. In addition, the display panel is prone to wire damage during the reliability test.

The present embodiment provides a display panel, which includes: a base substrate, a display structure layer, an encapsulation structure layer and a plurality of signal lead-out lines. The base substrate includes: a display region, a signal access region located on a side of the display region, and a peripheral wiring region located between the display region and the signal access region. The display structure layer is located in the display region. The encapsulation structure layer is located on a side of the display structure layer away from the base substrate. The encapsulation structure layer extends from the display region to the peripheral wiring region. The peripheral wiring region includes: a first region located on a side of the encapsulation boundary of the encapsulation structure layer close to the signal access region. A plurality of signal lead-out lines are located in the peripheral wiring region. At least one signal lead-out line includes: a first wire located in a first region, and the first wire is a double-layer wire.

In the display panel provided by the embodiment, by arranging the signal lead-out lines of the peripheral wiring region to adopt double-layer wire in the first region, the signal transmission effect of the peripheral wiring region can be improved, thereby improving the display effect.

In some exemplary implementations, the peripheral wiring region further includes a second region located on a side of the encapsulation boundary of the encapsulation structure layer close to the display region. A length of the first wire of the signal lead-out line extending to the second region may be less than or equal to 300 microns. For example, the length of the first wire extending to the second region may be about 300 microns. This example may match the encapsulation mode of the display panel and ensure the encapsulation effect of the display panel by arranging the first wire to extend to the second region where the encapsulation structure layer exists, wherein the extension length is less than or equal to 300 microns.

In some exemplary implementations, the first wire may include: a first sub-wire and a second sub-wire electrically connected to each other. The first sub-wire may be located on a side of the second sub-wire away from the base substrate, and orthographic projections of the first sub-wire and the second sub-wire on the base substrate may at least partially overlap. For example, the orthographic projection of the first sub-wire on the base substrate may coincide with the orthographic projection of the second sub-wire on the base substrate. In some examples, resistivity of a material of the first sub-wire may be smaller than resistivity of a material of the second sub-wire. For example, the material of the first sub-wire and the material of the second sub-wire may both be a metallic material. For example, the first sub-wire may adopt a titanium-aluminum-titanium stacked structure, and the material of the second sub-wire may include molybdenum. In this example, by arranging the first wire as a double-layer wire, the impedance of the signal lead-out line can be reduced, and the influence of the collapse of titanium on the top layer on signal transmission caused by the aluminum oxidation of the wiring of the titanium-aluminum-titanium stacked structure can be alleviated, thereby ensuring the display effect of the display panel. In addition, the wire damage of the display panel during the reliability test can be avoided.

In some exemplary implementations, at least one insulation layer may be provided between the first sub-wire and the second sub-wire, and the at least one insulation layer is provided with a plurality of vias arranged in an array, and the first sub-wire may be electrically connected to the second sub-wire through the plurality of vias. The first sub-wire and the second sub-wire of the present example are electrically connected through a plurality of vias arranged in an array, so that the parallel connection between the first sub-wire and the second sub-wire can be realized, thereby reducing the impedance of the signal lead-out line, and improving the display effect.

In some exemplary implementations, the peripheral wiring region may further include a second region located on a side of the encapsulation boundary of the encapsulation structure layer close to the display region. The at least one signal lead-out line may further include a second wire located in the second region, and the second wire and the first sub-wire of the first wire may form an integrated structure. In this example, the first sub-wire and the second wire of the second region are arranged in the same layer, for example, a titanium-aluminum-titanium stacked structure is adopted, which is conducive to reducing the impedance of the signal lead-out line, thereby improving the display effect.

The display panel according to this embodiment will be illustrated by some examples below.

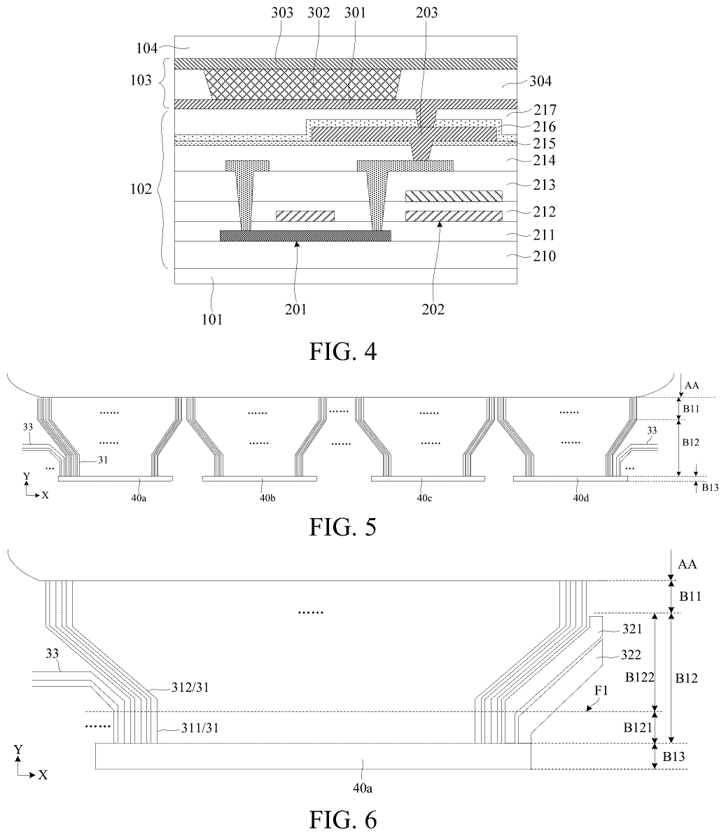

FIG. 4 is a schematic partial cross-sectional view of a structure of a display region of a display panel according to at least one embodiment of the present disclosure. FIG. 4 illustrates a structure of a sub-pixel of the display region. In some examples, as shown in FIG. 4, in a direction perpendicular to the display panel, the display panel may include: a base substrate 101, a display structure layer and an encapsulation structure layer 104 sequentially disposed on the base substrate 101. The display structure layer may include a circuit structure layer 102 and a light emitting structure layer 103 which are sequentially disposed on the base substrate 101. In some possible implementations, the display panel may include another film layer, such as a post spacer, which is not limited here in the present disclosure.

In some examples, the base substrate 101 may be a rigid substrate, e.g., a glass substrate. However, the present embodiment is not limited thereto.

In some examples, the circuit structure layer 102 of each sub-pixel may include a plurality of transistors and a storage capacitor which form a pixel circuit. Illustration is made in FIG. 4 by taking a transistor (e.g. the transistor 201) and a storage capacitor (e.g. the storage capacitor 202) included by a pixel circuit of a sub-pixel as an example. For example, the transistor 201 may be a sixth transistor or a seventh transistor in the pixel circuit, and the storage capacitor 202 may be a storage capacitor Cst in the pixel circuit.

In some examples, as shown in FIG. 4, the circuit structure layer 102 of a sub-pixel may include: a semiconductor layer, a first gate metal layer, a second gate metal layer, a first source-drain metal layer, and a second source-drain metal layer disposed on the base substrate 101. Herein, a buffer layer 210 may be provided between the semiconductor layer and the base substrate 101; a first insulation layer 211 may be provided between the semiconductor layer and the first gate metal layer; a second insulation layer 212 may be provided between the first gate metal layer and the second gate metal layer; and a third insulation layer 213 may be provided between the second gate metal layer and the first source-drain metal layer. A first planarization layer 214 and a first passivation layer 215 may be provided between the first source-drain metal layer and the second source-drain metal layer. The first passivation layer 215 may be located on a side of the first planarization layer 214 away from the base substrate 101. A second passivation layer 216 and a second planarization layer 217 may be sequentially provided on a side of the second source-drain metal layer away from the substrate 101. In this example, the second source-drain metal layer is disposed between the first passivation layer 215 and the second passivation layer 216, which can avoid the situation where the second source-drain metal layer cannot be deposited during the preparation process, and can ensure the display effect of the display panel.

In some examples, as shown in FIG. 4, the semiconductor layer may at least include an active layer of the transistor 201. The first gate metal layer may at least include: a gate electrode of the transistor 201 and a first capacitor plate of the storage capacitor 202. The second gate metal layer may at least include: a second capacitor plate of the storage capacitor 202, the orthographic projection of the second capacitor plate on the base substrate 101 may overlap with the orthographic projection of the first capacitor plate on the base substrate 101. The first source-drain metal layer may at least include: a first electrode and a second electrode of the transistor 201. The second source-drain metal layer may at least include: an anode connection electrode 203 which may electrically connect the second electrode of the transistor 201 and the anode 301 of the light emitting element. The active layer, the gate, the first electrode and the second electrode may constitute the transistor 201, and the first and second capacitor plates may form the storage capacitor 202.

In some examples, as shown in FIG. 4, the buffer layer 210, the first insulation layer 211, the second insulation layer 212, the third insulation layer 213, the first passivation layer 215, and the second passivation layer 217 may be inorganic insulation layers. For example, the buffer layer 210, the first insulation layer 211, the second insulation layer 212, the third insulation layer 213, the first passivation layer 215, and the second passivation layer 217 may be made of any one or more of Silicon Oxide (SiOx), Silicon Nitride (SiNx), and Silicon Oxynitride (SiON), and may be a single layer, a multi-layer, or a composite layer. Herein, the first insulation layer 211 and the second insulation layer 212 may be referred to as Gate Insulation (GI) layers, and the third insulation layer 213 may be referred to as an Interlayer Dielectric (ILD) layer. The first planarization layer 214 and the second planarization layer 216 may be organic insulation layers. The first gate metal layer, the second gate metal layer, the first source-drain metal layer, and the second source-drain metal layer may be made of a metal material, such as any one or more of silver (Ag), copper (Cu), aluminum (Al), titanium (Ti), and molybdenum (Mo), or an alloy material of the above metals, such as an Aluminum Neodymium (AlNd) alloy or a Molybdenum Niobium (MoNb) alloy, and may be in a single-layer structure or a multi-layer composite structure, such as Ti/Al/Ti. For example, the material of the first gate metal layer and the second gate metal layer may be molybdenum, and the material of the first source-drain metal layer may be a stacked structure of titanium-aluminum-titanium. The semiconductor layer may use a material such as polysilicon (p-Si).

In some examples, as shown in FIG. 4, the light emitting structure layer 103 may include an anode layer, a pixel definition layer 304, an organic emitting layer 302, and a cathode layer. The anode layer may include an anode 301 of the light emitting element, and the cathode layer may include a cathode 303 of the light emitting element. The anode 301 may be arranged on the second planarization layer 217, and is electrically connected to an anode connection electrode 203 through a via formed in the second planarization layer 217. The pixel definition layer 304 may be disposed on the anode layer and the second planarization layer 217, and the pixel definition layer 304 is provided with a pixel opening, and the pixel opening may at least expose a portion of a surface of the anode 301. The organic light emitting layer 302 is at least partially arranged in the pixel opening, and the organic light emitting layer 302 is connected to the anode 301. The cathode 303 is arranged on the organic light emitting layer 302, and the cathode 303 is connected to the organic light emitting layer 302. The organic light emitting layer 302 emits light of a corresponding color under the driving of the anode 301 and the cathode 302.

In some examples, the organic light emitting layer 302 may at least include a hole injection layer, a hole transport layer, a light emitting layer and a hole block layer which are stacked on the anode 301. In some examples, the hole injection layers of all sub-pixels may be a common layer connected together; the hole transport layers of all sub-pixels may be a common layer connected together; the light emitting layers of adjacent sub-pixels may be slightly overlapped or isolated; and the hole block layers may be a common layer connected together. However, the present embodiment is not limited thereto.

In some examples, as shown in FIG. 4, the encapsulation structure layer 104 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is arranged between the first encapsulation layer and the third encapsulation layer, which can ensure that outside water vapor cannot enter the light emitting structure layer 103.

FIG. 5 is a schematic diagram of a first peripheral region of a display panel according to at least one embodiment of the present disclosure. In some examples, as shown in FIG. 5, the first peripheral region of the display panel may include: a signal access region B13 located on a side of the display region AA, and a peripheral wiring region B12 and a peripheral circuit region B11 that are located between the display region AA and the signal access region B13. The peripheral circuit region B11 may be located on a side of the peripheral wiring region B12 close to the display region AA. In the second direction Y, the first peripheral region may include: the peripheral circuit region B11, the peripheral wiring region B12, and the signal access region B13 arranged sequentially in a direction away from the display region AA.

In some examples, the signal access region B13 may include a plurality of signal access pins arranged side by side and in parallel, and the plurality of signal access pins may be arranged sequentially in the first direction X. The plurality of signal access pins may be configured to form bonding connections with a flexible printed circuit or a driver chip, thereby acquiring signals from the flexible circuit board or the driver chip. For example, the signal access region B13 may be provided with a plurality of driver chips (e.g., driver chips 40a, 40b, 40c, and 40d). A plurality of driver chips may be arranged sequentially in the first direction X in the signal access region B13. However, the present embodiment is not limited thereto.

In some examples, as shown in FIG. 5, the peripheral circuit region B11 may be provided with a multi-channel multiplexing circuit and an electrostatic discharge circuit (ESD) (not shown). The electrostatic discharge circuit may be located at a side of the muti-channel multiplexing unit away from the display region AA. The muti-channel multiplexing circuit may include a plurality of multiplexing units, each multiplexing unit may be electrically connected with a plurality of data lines in the display region AA, and may be configured such that one signal source provides data signals to the plurality of data lines. For example, each multiplexing unit may be electrically connected to one multiplexing data line, and the multiplexing unit may be electrically connected to the signal source providing the data signal through the multiplexing data line. The multiplexing data line may be electrically connected to the electrostatic discharge circuit to discharge static electricity.

In some examples, as shown in FIG. 5, a plurality of signal lead-out lines may be provided in the peripheral wiring region B12, and the plurality of signal lead-out lines may include a plurality of data fan-out lines 31. The plurality of data fan-out lines 31 may be electrically connected to a plurality of multiplexing data lines of the peripheral circuit region B11. For example, a plurality of data fan-out lines 31 may be electrically connected to a plurality of multiplexing data lines in one-to-one correspondence. A plurality of data fan-out lines 31 may extend to the signal access region B13, and are electrically and correspondingly connected to a plurality of signal access pins within the signal access region B13. For example, the data fan-out lines 31 and the signal access pins may be electrically connected in one-to-one correspondence.

In some examples, as shown in FIG. 5, the plurality of signal lead-out lines may also include a plurality of drive control lines 33. The plurality of drive control lines 33 may be located on both sides of the plurality of data fan-out lines 31 in the first direction X. The plurality of drive control lines 33 may be electrically connected to the leftmost driver chip (e.g., driver chip 40a) and the rightmost driver chip (e.g., driver chip 40d). For example, the drive control lines 33 electrically connected to the driver chip 40a may extend to the third peripheral region to provide a control signal to the scan drive circuit in the third peripheral region. The drive control lines 33 electrically connected to the driver chip 40d may extend to the fourth peripheral region and provide a control signal to the light emitting drive circuit in the fourth peripheral region. However, the present embodiment is not limited thereto.

FIG. 6 is a schematic partial diagram of a first peripheral region according to at least one embodiment of the present disclosure. FIG. 6 is a schematic partial diagram of a portion of the first peripheral region closest to the third peripheral region in FIG. 5. In some examples, as shown in FIG. 6, within the peripheral wiring region B12, a plurality of data fan-out lines 31 extend in a fan-out wiring manner to the signal access region B13. The peripheral wiring region B12 is further provided with a first power supply line 321 and a second power supply line 322. For a driver chip located on an edge in the first direction X, the first power supply line and the second power supply line may be located on a side of a plurality of data fan-out lines 31 electrically connected to the driver chip close to a middle line of the display panel in the first direction X. For a driver chip of adjacent driver chips on both sides in the first direction X, a first power supply line and a second power supply line may be located on two sides of a plurality of data fan-out lines 31 electrically connected to the driver chip. For example, the first power line 321 and the second power line 322 may be located on a side of the plurality of data fan-out lines 31 electrically connected to the driver chip 40a close to the fourth peripheral region, and the plurality of drive control lines 33 may be located on a side of the plurality of data fan-out lines 31 electrically connected to the driver chip 40a close to the third peripheral region. For example, one end of the first power supply line 321 may extend to the signal access region B13 and be electrically connected to the driver chip 40a through a signal access pin, and the other end may extend to the display region and be electrically connected to the sub-pixels. One end of the second power supply line 322 may extend to the signal access region B13 and be electrically connected to the driver chip 40a through the signal access pin, and the other end may extend to the display region and be electrically connected to the sub-pixels. The second power supply line 322 may be located on a side of the first power supply line 321 away from the plurality of data fan-out lines 31.

In some examples, as shown in FIG. 6, the line widths of the first power supply line 321 and the second power supply line 322 may be greater than the line widths of the data fan-out lines 31, or may be greater than the line widths of the drive control lines 33. In this example, the line width represents the length of the wire in the vertical direction of the extension direction within the wire extension plane.

In some examples, as shown in FIG. 6, the encapsulation structure layer may extend from the display region AA to the first peripheral region. The encapsulation boundary F1 of the encapsulation structure layer in the first peripheral region may be the boundary of the inorganic encapsulation layer of the encapsulation structure layer. The peripheral wiring region B12 may include a first region B121 and a second region B122. The first region B121 may be a region on a side of the encapsulation boundary F1 close to the signal access region B13, and the second region B122 may be a region on a side of the encapsulation boundary F1 close to the display region AA. In other words, the encapsulation boundary F1 of the encapsulation structure layer may divide the peripheral wiring region B12 into a first region B121 and a second region B122. The first region B121 does not have an encapsulation structure layer, and the second region B122 may be provided with an encapsulation structure layer.

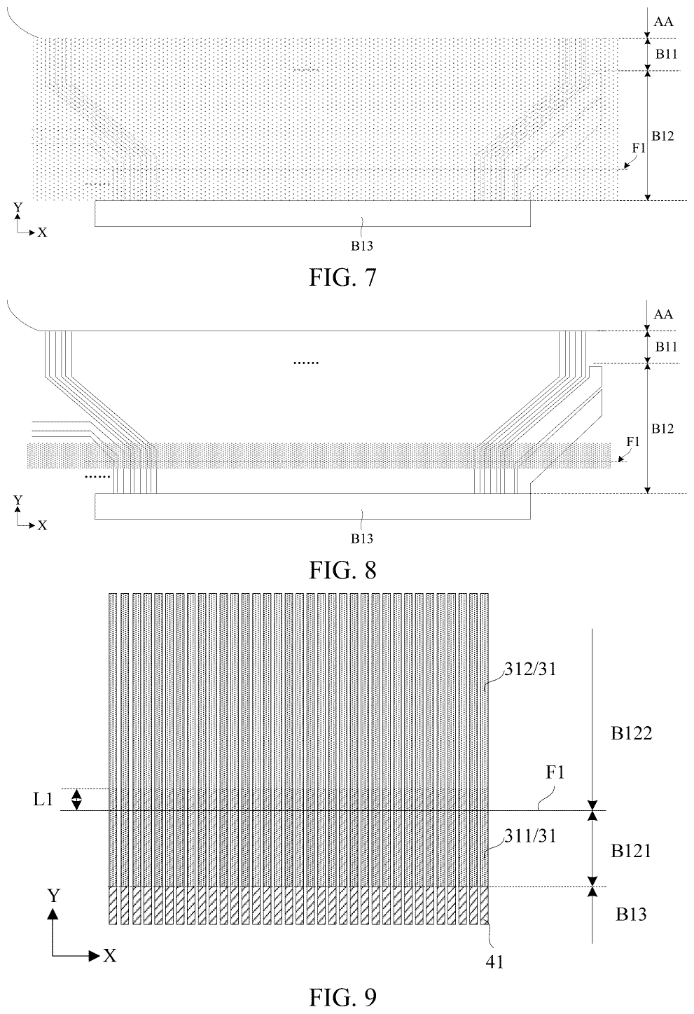

FIGS. 7 and 8 are partial schematic diagrams of film layers of a first peripheral region according to at least one embodiment of the present disclosure. In some examples, the shadow region shown in FIG. 7 is a hole-digging region for the pixel definition layer. The pixel definition layer in the shadow region of FIG. 7 is removed. For example, a pixel definition layer within the first peripheral region may be removed. The shadow region shown in FIG. 8 is a first isolation region. At least one of the first planarization layer and the second planarization layer within the first isolation region may be removed. For example, both the first planarization layer and the second planarization layer within the first isolation region may be removed. An orthographic projection of the encapsulation boundary F1 of the encapsulation structure layer on the base substrate may be located in the first isolation region. The first isolation region may be located at the junction of the first region B121 and the second region B122 of the peripheral wiring region B12, and overlap with the first region B121 and the second region B122, respectively. In some examples, the length of the first isolation region in the second direction Y may be from about 270 microns to about 330 microns, for example, may be about 300 microns. In this example, by arranging the first isolation region in the peripheral wiring region, water vapor can be blocked from entering the display region to avoid affecting the display effect.

In some examples, as shown in FIGS. 6 to 8, wires of the data fan-out lines 31 and the drive control lines 33 located within the first region B121 may be double-layer wires. An encapsulation structure layer is provided in the overlapping region of the second region B122 and the first isolation region to ensure the encapsulation effect; the encapsulation structure layer and a planarization layer are not provided in the overlapping region of the first region B121 and the first isolation region; the signal transmission effect can be guaranteed by arranging the signal lead-out lines as double-layer wires, and the encapsulation mode of the display panel can also be matched. In some examples, since the line widths of the first power supply line 321 and the second power supply line 322 are relatively large, the wires of the first power supply line 321 and the second power supply line 322 in the first region B121 are single-layer wires, and the signal transmission effect can still be guaranteed. However, the present embodiment is not limited thereto. In some other examples, the wires of the first power supply line and the second power supply line in the first region may be double-layer wires to further guarantee the signal transmission effect.

The data fan-out line is taken as an example to illustrate the structure of the signal lead-out line in the peripheral wiring region.

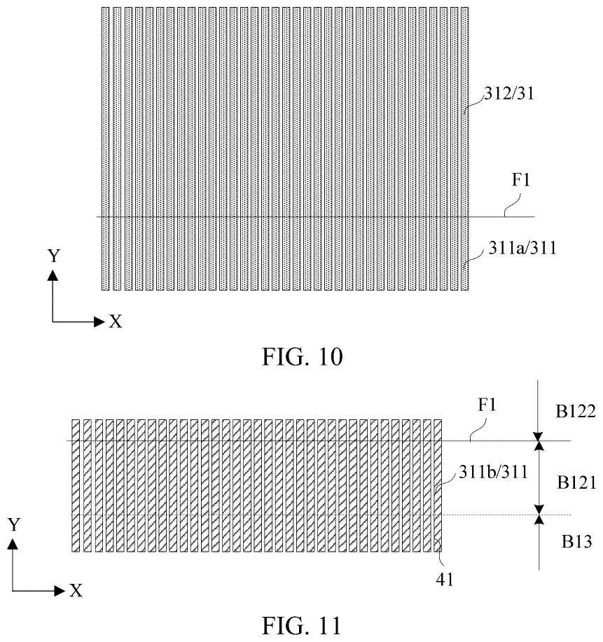

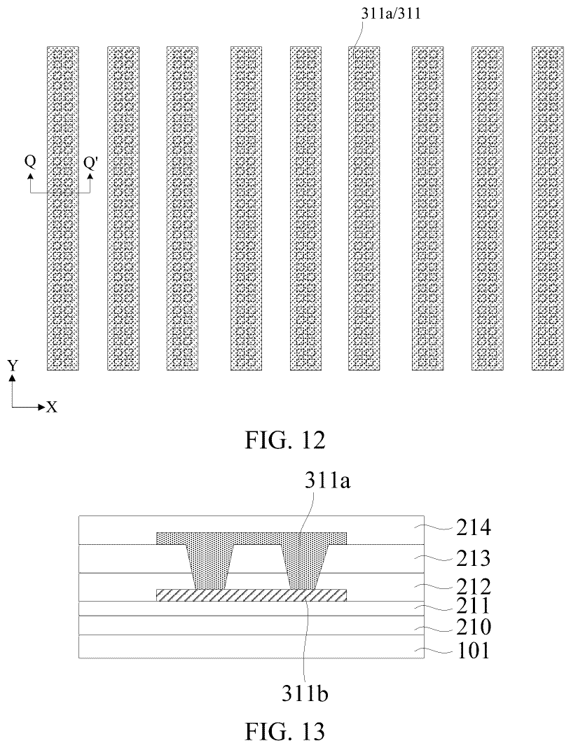

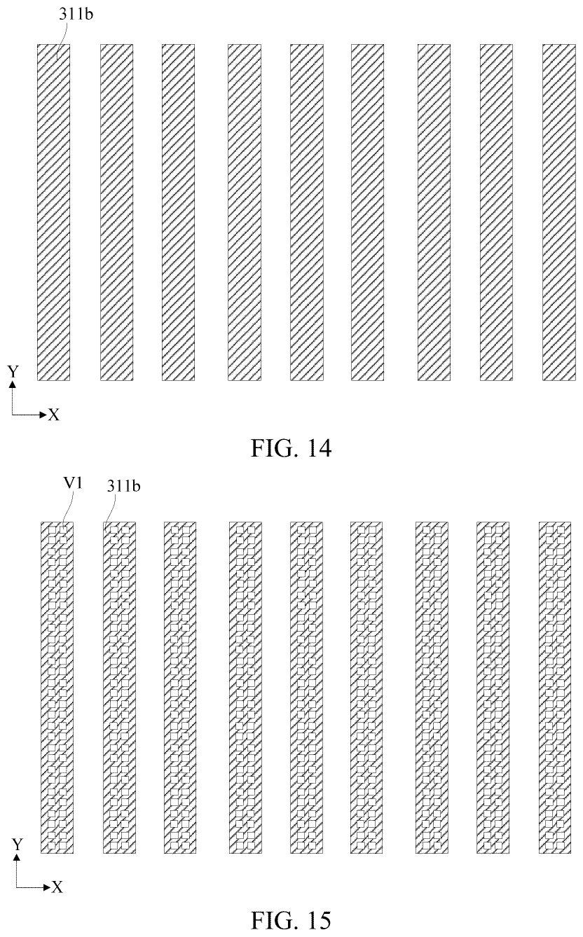

FIG. 9 is a schematic partial diagram of a peripheral wiring region according to at least one embodiment of the present disclosure. FIG. 10 is a schematic diagram of a first source-drain metal layer in FIG. 9. FIG. 11 is a schematic diagram of a first gate metal layer in FIG. 9. FIG. 12 is a schematic partial diagram of a first region according to at least one embodiment of the present disclosure. FIG. 13 illustrates schematically a partial cross-sectional view taken along a direction Q-Q′ in FIG. 12. FIG. 14 is a schematic diagram of a first gate metal layer in FIG. 12. FIG. 15 is a schematic partial diagram of a first region after a second insulation layer is formed in FIG. 12.

In some examples, as shown in FIGS. 9 to 11, the data fan-out lines 31 may include first wires 311 located in the first region B121 and second wires 312 located in the second region B122. The first wire 311 may be a double-layer wire, and may include, for example, a first sub-wire 311a and a second sub-wire 311b electrically connected to each other. The first sub-wire 311a may be located on a side of the second sub-wire 311b away from the base substrate. Orthographic projections of the first sub-wire 311a and the second sub-wire 311b on the base substrate may at least partially overlap. For example, the orthographic projection of the first sub-wire 311a on the substrate may coincide with the orthographic projection of the second sub-wire 311b on the substrate, or the orthographic projection of the first sub-wire 311a on the substrate may be within the orthographic projection of the second sub-wire 311b on the substrate. The second wire 312 may be a single-layer wire. The second wire 312 may be electrically connected to the first sub wire 311a, for example, may from an integrated structure with the first sub wire 311a. The second sub-wire 311b may be electrically connected to the signal access pin 41 within the signal access region B13. For example, the second sub-wire 311b and the connected signal access pin 41 may be an integrated structure.

In some examples, as shown in FIG. 9, the first wire 311 may extend into the second region B122. For example, the extension length L1 of the first wire 311 in the second region B122 may be less than or equal to 300 microns, for example, may be about 300 microns. In some examples, there is a certain error range for the encapsulation boundary of the encapsulation structure layer during the preparation process of the display panel. By arranging a part of the length of the first wires to extend to the second region, the arrangement of the wires can be made to better match the encapsulation mode, and the poor encapsulation at the junction of the first region and the second region due to the error of the encapsulation boundary can be avoided, thereby ensuring the signal transmission effect.

In some examples, as shown in FIG. 14, the first gate metal layer of the peripheral wiring region may include second sub-wires 311b of the first wire 311 of the plurality of data fan-out lines 31. The plurality of second sub-wires 311b may extend in the second direction Y and be sequentially arranged in the first direction X. As shown in FIG. 15, the third insulation layer 213 of the peripheral wiring region may be provided with a plurality of vias V1. The third insulation layer 213 and the second insulation layer 212 within the plurality of vias V1 may be removed, exposing the surface of the second sub-wire 311b located in the first gate metal layer. The plurality of vias V1 may be arranged in an array. For example, a plurality of vias V1 corresponding to a first sub-wire 311a may be arranged in two lines in a first direction X and in a plurality of rows in a second direction Y. As shown in FIG. 12, the first source-drain metal layer of the peripheral wiring region may include first sub-wires 311a of first wires 311 of a plurality of data fan-out lines 31. The plurality of first sub-wires 311a may extend in the second direction Y and be sequentially arranged in the first direction X. The first sub-wires 311a may be electrically connected to the second sub-wires 311b through a plurality of vias V1 provided in the third insulation layer 213. In this example, the electrical connection of the first sub-wires and the second sub-wires is realized by opening a plurality of vias, which is equivalent to connecting a plurality of parts of the first sub-wires and the second sub-wires in parallel, which is conducive to reducing the impedance of the first wires and improving the display effect. However, the present embodiment is not limited thereto. In some other examples, the second sub-wires of the first wires of the data fan-out line may be located in the second gate metal layer, and the second sub-wires may be electrically connected to the first sub-wires located in the first source-drain metal layer through vias provided in the third insulation layer.

In some examples, as shown in FIGS. 9 to 15, the signal access pins 41 of the signal access region B13 may be located in the first gate metal layer. At least one signal access pin 41 is electrically connected to a second sub-wire 311b of a first wire 311 of the data fan-out line 31. The second wires 312 of the second region B122 may be located in the first source-drain metal layer and electrically connected to the first sub-wires 311a of the first wires 311. However, the present embodiment is not limited thereto. In some other examples, a signal access pin of the signal access region B13 may be a double-layer structure, for example, may include a first sub-pin located on the first gate metal layer and a second sub-pin located on the first source-drain metal layer. The second sub-pin may be electrically connected to a first sub-wire of a first wire of a data fan-out line, for example, may form an integrated structure. The first sub-pin may be electrically connected to a second sub-wire of the first wire of the data fan-out line, for example, may form an integrated structure.

In some examples, the first power supply line and the second power supply line of the peripheral wiring region may be located in the first source-drain metal layer.

In some examples, the resistivity of the material of the first sub-wire 311a of the first wire 311 of the data fan-out line 31 may be smaller than the resistivity of the material of the second sub-wire 311b, thereby reducing the wire impedance and reducing the signal transmission load. For example, the first sub-wire may adopt a titanium (Ti)/aluminum (Al)/Ti stacked structure, and the material of the second sub-wire may be molybdenum (Mo). Since the planarization layer in the overlapping region of the first isolation region and the first region B121 is removed, it is prone to cause the collapse of the top titanium and the aluminum oxidation of the first source-drain metal layer to affect the signal transmission during the preparation process. In this example, by arranging double-layer wires in the first region, the situation where the collapse of the top titanium caused by aluminum oxidation affects the signal transmission during the preparation process can be alleviated. The first gate metal layer and the first source-drain metal layer are used to transmit signals, and the signal transmission effect can be guaranteed to ensure the display effect. Moreover, the first region is not covered by the encapsulation structure layer, which is prone to cause the wire damage of the titanium/aluminum/titanium stacked structure (for example, the wire damage is prone to occur during the reliability test). After the wiring arrangement of the peripheral wiring region is improved in this example, the requirements of the reliability test can be met, and the wire damage caused during the reliability test can be reduced.

A preparation process of the display panel will be exemplarily described below. A “patterning process” mentioned in the present disclosure includes processings such as film layer deposition, photoresist coating, mask exposure, development, etching, and photoresist stripping. The deposition may be any one or more of sputtering, evaporation, and chemical vapor deposition, the coating may be any one or more of spray coating and spin coating, and the etching may be any one or more of dry etching and wet etching. A “thin film” refers to a layer of a thin film prepared from a material on a base substrate using a process of deposition or coating. If the “thin film” does not need to be processed with a patterning process throughout the whole manufacturing process, the “thin film” may also be called a “layer”. When the “thin film” further needs a patterning process throughout the whole manufacturing process, it is referred to as a “thin film” before the patterning process and as a “layer” after the patterning process. At least one “pattern” is contained in the “layer” which has been processed with the patterning process.

“A and B are of a same layer structure” mentioned in the present disclosure means that A and B are formed simultaneously through a same patterning process. A “same layer” does not always mean that thicknesses of layers or heights of layers are the same in a section diagram. “An orthographic projection of A contains an orthographic projection of B” means that the orthographic projection of B falls within a range of the orthographic projection of A, or the orthographic projection of A covers the orthographic projection of B.

In some examples, the process for preparing a display panel of the embodiment may include following acts.

(1) A base substrate is provided. In some examples, the base substrate may be a rigid substrate, e.g., a glass substrate.

(2) A semiconductor film is prepared. In some examples, a buffer film and a semiconductor film are sequentially deposited on the base substrate, and the semiconductor film is patterned by a patterning process to form the semiconductor layer. For example, the semiconductor layer of the display region may include an active layer of the transistor of the pixel circuit.

(3) A first gate metal layer is prepared. In some examples, a first insulation thin film and a first metal thin film are sequentially deposited on the base substrate where the aforementioned structures are formed, and the first metal thin film is patterned through a patterning process to form a first insulation layer covering the semiconductor layer and to form a first gate metal layer arranged on the first insulation layer. For example, the first gate metal layer of the display region may include: a gate of a transistor of a pixel circuit and a first capacitor plate of a storage capacitor. The first gate metal layer of the first peripheral region may include: second sub-wires of the first wires of the signal lead-out lines (e.g., including the data fan-out lines, drive control lines) located in the first region of the peripheral wiring region, and a plurality of signal access pins located in the signal access region.

(4) A second gate metal layer is prepared. In some examples, a second insulation thin film and a second metal thin film are sequentially deposited on the base substrate where the aforementioned structures are formed, and the second metal thin film is patterned through a patterning process to form a second insulation layer covering the first gate metal layer and to form a second gate metal layer disposed on the second insulation layer. For example, the second gate metal layer of the display region may include a second capacitor plate of the storage capacitor of the pixel circuit.

(5) A third insulation layer is prepared. In some examples, a third insulation thin film is deposited on the base substrate where the aforementioned structures are formed, and the third insulation thin film is patterned through a patterning process to form a third insulation layer. For example, the third insulation layer of the display region is provided with a plurality of pixel vias. The plurality of pixel vias may expose surface of the semiconductor layer, the first gate metal layer, or the second gate metal layer. The third insulation layer of the first peripheral region is provided with a plurality of vias, and the third insulation layer and the second insulation layer in the plurality of vias may be removed to expose a part of the surface of the second sub-wire located in the first gate metal layer.

(6) A first source-drain metal layer is prepared. In some examples, a third metal thin film is deposited on the base substrate where the aforementioned structures are formed, and the third metal thin film is patterned through a patterning process to form a first source-drain metal layer. For example, the first source-drain metal layer of the display region may include: a first electrode and a second electrode of the transistor of the pixel circuit. The first source-drain metal layer of the first peripheral region may include: the second wires and the first sub-wires of the first wires of the signal lead-out lines (including, for example, data fan-out lines and drive control lines) located in the peripheral wiring region, the first power supply line, and the second power supply line.

(7) A second source-drain metal layer is prepared. In some examples, a first planarization film is coated on the base substrate where the aforementioned structures are formed, and a first planarization layer is formed by a patterning process; then a first passivation film is deposited, and a first passivation layer is formed by a patterning process; subsequently, a fourth metal film is deposited, and the fourth metal film is patterned through the patterning process to form the second source-drain metal layer. For example, the second source-drain metal layer of the display region may include an anode connection electrode which may connect the anode of the light emitting element and the pixel circuit. Subsequently, a second passivation film is deposited to form a second passivation layer by a patterning process. Subsequently, a second planarization film is coated to form a second planarization layer by a patterning process. Herein the first planarization layer and the second planarization layer within the first isolation region of the first peripheral region may be removed.

(8) A light emitting structure layer is prepared. In some examples, an anode film is deposited on the base substrate where the aforementioned structure are formed, and the anode film is patterned by a patterning process to form an anode layer. Subsequently, the pixel definition film is coated, and the pixel definition layer pattern is formed through mask, exposure, and development processes. The pixel definition layer is formed in the display region. Subsequently, an organic light emitting layer and a cathode layer are sequentially formed on the base substrate on which the aforementioned patterns are formed. For example, the organic light emitting layer includes a hole injection layer, a hole transport layer, a light emitting layer, an electron transport layer, and an electron injection layer that are stacked, and is formed in the pixel opening of the display region, to connect the organic light emitting layer to the anode. A part of the cathode layer is formed on the organic light emitting layer.

(9) An encapsulation structure layer is prepared. In some examples, an encapsulation structure layer may be a stacked structure of inorganic material/organic material/inorganic material. For example, an inorganic material may be deposited by chemical vapor deposition to form an inorganic encapsulation layer. The encapsulation boundary of the encapsulation structure layer in the first peripheral region may be located in the aforementioned first isolation region. In the overlapping region of the first isolation region and the first region of the peripheral wiring region, there is no planarization layer and encapsulation structure layer. When the wires located in the first source-drain metal layer adopt a titanium-aluminum-titanium stacked structure, during the preparation process, aluminum oxidation will lead to the collapse of titanium on the top layer and then cause poor signal transmission. In this example, by arranging the wires in the first region as double-layer structure (located in the first gate metal layer and the first source-drain metal layer), the signal transmission caused by the collapse of titanium on the top layer caused by aluminum oxidation can be improved. The signal transmission effect can be guaranteed, the wire impedance can be reduced, and the display effect can be improved.

The preparation process according to the exemplary embodiment may be achieved using an existing mature preparation device, and may be well compatible with an existing preparation process. The process is simple to achieve, easy to implement, high in an efficiency of production, low in a production cost, and high in a yield.

The structure of the display panel of the exemplary embodiment and the preparation process thereof are described only as an example. In some exemplary implementations, a corresponding structure may be changed and a patterning process may be added or removed according to actual needs. For example, second sub-wires of the first wires of the signal lead-out lines of the first peripheral region may be located in the second gate metal layer. For another example, the plurality of signal lead-out lines may include: a plurality of data fan-out lines, and the plurality of drive control lines may adopt single-layer wire. The present embodiment is not limited thereto.

A display device is also provided in an embodiment of the present disclosure, including the display panel in the aforementioned embodiments. The display panel may be an OLED display panel. The display device may be any product or component with a display function, such as an OLED display device, a mobile phone, a tablet computer, a television, a display, a notebook computer, a digital photo frame, and a navigator. However, the present embodiment is not limited thereto.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display panel, comprising:
a base substrate, comprising at least: a display region, a signal access region located on a side of the display region, and a peripheral wiring region located between the display region and the signal access region;
a display structure layer, located in the display region;
an encapsulation structure layer, located on a side of the display structure layer away from the base substrate, wherein the encapsulation structure layer extends from the display region to the peripheral wiring region; and the peripheral wiring region comprises: a first region located on a side of an encapsulation boundary of the encapsulation structure layer close to the signal access region; and
a plurality of signal lead-out lines, located in the peripheral wiring region, wherein at least one signal lead-out line comprises: a first wire located in the first region, and the first wire is a double-layer wire.

2. The display panel of claim 1, wherein the peripheral wiring region further comprises: a second region located on a side of the encapsulation boundary of the encapsulation structure layer close to the display region; and a length of the first wire extending to the second region is less than or equal to 300 microns.

3. The display panel of claim 1, wherein the first wire comprises a first sub-wire and a second sub-wire electrically connected to each other, the first sub-wire is located on a side of the second sub-wire away from the base substrate; and orthographic projections of the first sub-wire and the second sub-wire on the base substrate at least partially overlap.

4. The display panel of claim 3, wherein a resistivity of a material of the first sub-wire is less than a resistivity of a material of the second sub-wire.

5. The display panel of claim 4, wherein the material of the first sub-wire and the material of the second sub-wire are both a metal material.

6. The display panel of claim 5, wherein the first sub-wire is a titanium-aluminum-titanium stacked structure, and the material of the second sub-wire comprises molybdenum.

7. The display panel of claim 3, wherein at least one insulation layer is provided between the first sub-wire and the second sub-wire, and the at least one insulation layer is provided with a plurality of vias arranged in an array, and the first sub-wire is electrically connected to the second sub-wire through the plurality of vias.

8. The display panel of claim 3, wherein the peripheral wiring region further comprises a second region located on a side of the encapsulation boundary of the encapsulation structure layer close to the display region; the at least one signal lead-out line further comprises a second wire located in the second region, and the second wire and the first sub-wire of the first wire form an integrated structure.

9. The display panel of claim 3, wherein the signal access region comprises a plurality of signal access pins, and the second sub-wire is electrically connected to at least one signal access pin.

10. The display panel of claim 3, wherein in a direction perpendicular to the display panel, the display panel comprises: a semiconductor layer, a first gate metal layer, a second gate metal layer, a first source-drain metal layer, and a second source-drain metal layer, which are sequentially arranged on the base substrate;
wherein the first sub-wire is located on the first source-drain metal layer, and the second sub-wire is located on the first gate metal layer or the second gate metal layer.

11. The display panel of claim 10, wherein a first planarization layer and a first passivation layer are sequentially disposed between the first source-drain metal layer and the second source-drain metal layer, and a second passivation layer and a second planarization layer are sequentially disposed on a side of the second source-drain metal layer away from the base substrate.

12. The display panel of claim 11, wherein the peripheral wiring region has a first isolation region, at least one of a first planarization layer and a second planarization layer within the first isolation region is removed, the first isolation region partially overlaps with the encapsulation structure layer; and the first wire partially overlaps with the first isolation region.

13. The display panel of claim 1, wherein the plurality of signal lead-out lines comprise a plurality of data fan-out lines; or comprise: a plurality of data fan-out lines and a plurality of drive control lines.

14. The display panel of claim 1, wherein the base substrate is a rigid substrate.

15. A display device, comprising the display panel of claim 1.

16. The display panel of claim 13, wherein the peripheral wiring region is further provided with a first power supply line and a second power supply line.

17. The display panel of claim 16, wherein line widths of the first power supply line and the second power supply line are greater than a line width of a data fan-out line or a line width of a drive control line.

18. The display panel of claim 9, wherein the plurality of signal access pins are located on a first gate metal layer.

19. The display panel of claim 9, wherein the plurality of signal access pins are of a double-layer structure.

20. The display panel of claim 16, wherein the first power supply line and the second power supply line are located on a first source-drain metal layer.
